(19) United States
(12) Patent Application Publication
(10) Pub. No.: US 2022/0393575 A1
(43) Pub. Date: Dec. 8, 2022

(54) OSCILLATION-DRIVEN THERMOELECTRIC POWER GENERATION

(71) Applicant: Calagen, Inc., Portland, OR (US)

(72) Inventors: David Reginald Carver, Baton Rouge, LA (US); Sean Williams Reynolds, Baton Rouge, LA (US); Sean Claudius Hall, Baton Rouge, LA (US)

(73) Assignee: Calagen, Inc., Portland, OR (US)

(21) Appl. No.: 17/583,949

(22) Filed: Jan. 25, 2022

Related U.S. Application Data
(63) Continuation of application No. 16/137,338, filed on Sep. 20, 2018, now abandoned.
(60) Provisional application No. 62/568,244, filed on Oct. 4, 2017.

(51) Int. Cl. H02M 3/00; H01L 35/30; H02M 11/00; H02P 7/00

(52) U.S. Cl. CPC H02M 3/00; H01L 35/30; H02M 11/00; H02P 7/00; H03B 5/08

(57) ABSTRACT

An apparatus can comprise a circuit and an electrical element coupled to the circuit. The circuit can include a pulse generator to generate an electrical pulse having a first power and a load. The electrical element can be configured to receive heat that is converted into electrical energy by the circuit to apply a second power, greater than the first power, to the load.

### CROSS REFERENCE TO RELATED APPLICATION

This application is a continuation of U.S. application Ser. No. 16/137,338, filed on Sep. 20, 2018, which claims priority from U.S. Provisional Application No. 62/568,244, filed Oct. 4, 2017, which applications are incorporated herein by reference in their entirety.

### FIELD

This invention relates to power generation. More specifically, this invention relates to oscillation-driven thermoelectric power generation.

### BACKGROUND

Thermoelectric generators rely on a thermal gradient formed between different nodes of a circuit to produce electrical energy. In some instances, the nodes may comprise two or more dissimilar materials. In other instances, the nodes can be part of a single material.

### SUMMARY

The following disclosure relates to improvements in thermoelectric power generation. The embodiments disclosed herein provide methods and apparatus for converting thermal energy into electrical energy.

In one representative embodiment, an apparatus can comprise a circuit and an electrical element coupled to the circuit. The circuit can include a pulse generator to generate an electrical pulse having a first power and a load. The electrical element can be configured to receive heat that is converted into electrical energy by the circuit to apply a second power, greater than the first power, to the load.

In any of the disclosed embodiments, at least a portion of the electrical element can be coupled to a heat sink. In any of the disclosed embodiments, the heat can be applied to the heat sink.

In any of the disclosed embodiments, the heat can be applied to the electrical element such that there is a thermal gradient across a length of at least a portion of the electrical element. In any of the disclosed embodiments, the electrical element can comprise a wire having a heavier gauge (i.e., a wider diameter) than conductors within the circuit that couple the electrical element to other circuit components. In any of the disclosed embodiments, a portion of the electrical pulse generated by the pulse generator can have a change in voltage with respect to time of at least 100 volts per microsecond.

In any of the disclosed embodiments, the circuit can further comprise an oscillator connected in series with the electrical element. In any of the disclosed embodiments, the circuit can further comprise an oscillator connected in parallel with the electrical element.

In any of the disclosed embodiments, the circuit can further comprise a primary oscillator and a secondary oscillator connected in series with the electrical element. In any of the disclosed embodiments, at least one of the primary or secondary oscillator can be an LC circuit.

In any of the disclosed embodiments, a rising voltage of the electrical pulse can cause the primary oscillator to oscillate at a first frequency and the secondary oscillator to oscillate at a second frequency greater than the first frequency. In any of the disclosed embodiments, the circuit can further comprise an inductive element and/or a capacitor tap connected in series with the secondary oscillator.

In another representative embodiment, a method can comprise generating an electrical pulse as an input to a circuit comprising a first portion with a load and a second portion with an electrical element connected to the load, absorbing heat within the electrical element, converting the absorbed heat into electrical energy to increase a power of the electrical pulse, and applying the electrical pulse with increased power to the load.

In any of the disclosed embodiments, at least a portion of the electrical element can be coupled to a heat sink. In any of the disclosed embodiments, the method can further comprise applying the heat to the heat sink.

In any of the disclosed embodiments, the method can further comprise applying the heat to the electrical element such that there is a thermal gradient across a length of at least a portion of the electrical element. In any of the disclosed embodiments, a portion of the electrical pulse can have a change in voltage with respect to time of at least 100 volts per microsecond. In any of the disclosed embodiments, the first portion of the circuit can further comprise an oscillator positioned in series with the electrical element. The oscillator can cause the circuit to convert the absorbed heat into useful electrical energy.

In any of the disclosed embodiments, the first portion of the circuit can further comprise a primary oscillator and a secondary oscillator connected in series with the electrical element. In any of the disclosed embodiments, a rising voltage of the electrical pulse can cause the primary oscillator to oscillate at a first frequency and the second oscillator to oscillate at a second frequency greater than the first frequency.

In any of the disclosed embodiments, generating the electrical pulse can comprise during a first time interval, opening a second switch connected to ground and then closing a first switch connected to a power supply, and during a second time interval, opening the first switch and then closing the second switch.

In another representative embodiment, an apparatus can comprise a circuit and an electrical element coupled to the circuit. The circuit can include a pulse generator to generate an electrical pulse and a primary oscillator coupled to the pulse generator. The circuit can be configured to supply the electrical pulse to a load with a greater power than the power supplied by the pulse generator. In any of the disclosed embodiments, the circuit can further comprise a secondary oscillator coupled to the primary oscillator.

The foregoing and other objects, features, and advantages of the invention will become more apparent from the following detailed description, which proceeds with reference to the accompanying figures.

### BRIEF DESCRIPTION OF THE DRAWINGS

FIG. 1 is a block diagram of an exemplary thermoelectric power generation system.

FIG. 2 is a block diagram of another exemplary thermoelectric power generation system that includes a heat sink.

FIG. 3 is a block diagram of another exemplary thermoelectric power generation system that includes an oscillator.

FIG. 4 is a block diagram of another exemplary thermoelectric power generation system that includes a primary and a secondary oscillator.

FIG. 5 is a block diagram of another exemplary thermoelectric power generation system that includes an LC oscillator.

FIG. 6 is a block diagram of another exemplary thermoelectric power generation system.

FIG. 7 is a block diagram of another exemplary thermoelectric power generation system.

FIG. 8 is a block diagram of another exemplary thermoelectric power generation system.

FIG. 9 is a block diagram of another exemplary thermoelectric power generation system.

FIG. 10 is a timing diagram of voltages present in the thermoelectric transducer of FIG. 9.

FIG. 11 illustrates an exemplary method of operating the thermoelectric power generation systems of FIGS. 1-9.

### DETAILED DESCRIPTION

This disclosure concerns embodiments of thermoelectric transducers that can be used for thermoelectric power generation. Traditional thermoelectric devices are an inefficient means of converting thermal energy into electrical energy. One reason for this inefficiency is the lack of control in transporting thermodynamic from a heat source to a heat sink due to diffusion (e.g., Newton cooling). However, an oscillating source of heat applied to a thermoelectric conductor can result in a considerable increase in the thermoelectric efficiency of the conductor.

Various improvements to thermoelectric power generation are disclosed herein. The disclosed embodiments can be used for various applications requiring power such as transportation (e.g., marine, ground, flight), remote location systems including autonomous powering of Internet of Things devices, power for sensing, tracking, communication, analytics, processing and interoperability of devices, powering of wearables, smart textiles with embedded electronics, among other applications. Additionally, embodiments disclosed herein can be used for power intensive applications and processes such as water purification, vertical and traditional agriculture, chemical and petrochemical processing, data center power and cooling, facility and environmental controls (e.g., industrial, commercial, residential). The embodiments disclosed herein can also complement existing power infrastructures including as a complement to solar farm infrastructure, wind and other intermittent renewable energy systems, dual purpose power sources, data centers, thermal management or cooling mechanisms (e.g., heat sinks), charging mechanisms for energy storage devices, lighting power sources, and as an integral power source for consumer electronics including telecommunications devices. Additionally, embodiments described herein can be used with home and industrial devices such as refrigeration and other cooling applications (e.g., air conditioning) and in combination with structural or other surfaces (e.g., roofing). More generally, anything that can be powered by electrical means can be supported by the embodiments disclosed herein regardless of the availability of an externally connected power source.

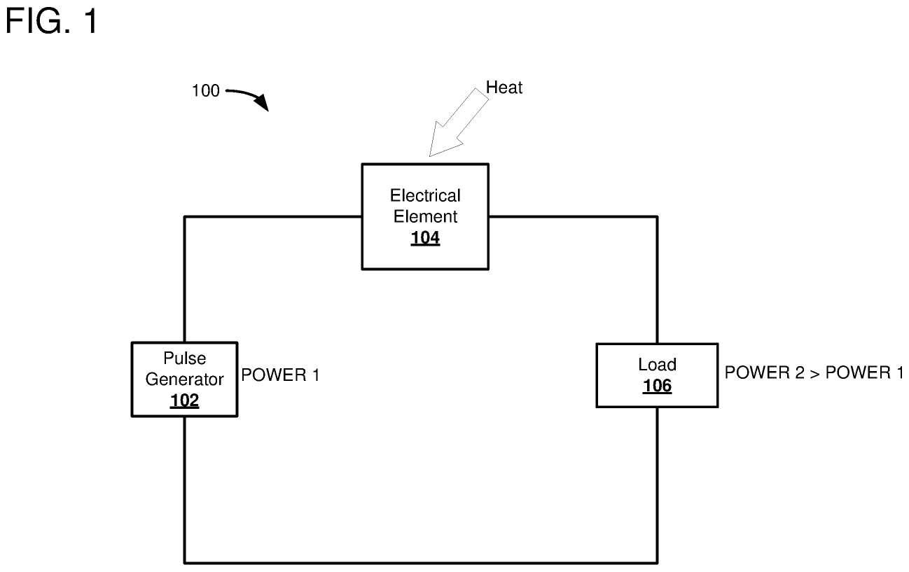

FIG. 1 shows an embodiment of a thermoelectric power generation system or circuit 100. The circuit 100 comprises a pulse generator 102, an electrical element 104, and a load 106. The pulse generator 102 can be a device that generates an electrical pulse. In some embodiments, the pulse generator 102 can generate a continuous stream of electrical pulses at periodic intervals. Ideally, the pulse generator 102 generates an electrical pulse in which the voltage output by the pulse generator increases rapidly over a short period of time. This could be done with a square wave with a short rise time, or a sine wave, a saw-tooth wave, or similar output voltage wave with a high frequency. The circuit 100 can generate thermoelectric power with an electrical pulse output by the pulse generator 102 having a dV/dt as small as 100 V/s. Results indicate that a good efficiency can be obtained with sinusoidal signals having a frequency as low as 4.7 kHz and in certain cases as low as 900 Hz. However, ideally the pulse generator 102 outputs a pulse having a dV/dt of at least 100 V/μs or preferably 10,000 to 100,000 V/μs or higher.

When the pulse generator 102 outputs an electrical pulse having a high dV/dt, the electrical element 104 converts thermal energy to electrical energy, as described herein. The electrical element 104 should have a conductive path with sufficient surface area to absorb heat, thereby allowing the electrical element to act as a heat sink. This can be achieved by the electrical element 104 having a heavier gauge, a greater length, or a non-cylindrical shape with greater surface area. In some examples, the electrical element 104 can be a copper wire having a gauge (e.g., 10 AWG) that is heavier than the wires or electrical conductor connecting the electrical element to the pulse generator 102 and the load 106. In other examples, the electrical element 104 can comprise any other conductive material. In one example, the electrical element 104 is a heavier gauge wire with respect to other signal conductors in the circuit and has a length of at least three feet. The electrical element 104 can be a simple wire, a coil, or any conductive element that can absorb heat. When the electrical pulse output by the pulse generator 102 with a high dV/dt ratio is applied to one side of the electrical element 104, the electrical element gets colder and a voltage appears on the other side the electrical element with a higher power level than what was produced by the pulse generator 102. As such, the sharp pulse output by the pulse generator 102 causes the electrical element 104 to convert thermal energy into electrical energy. The higher the dV/dt ratio of the pulse output by the pulse generator 102, the greater the amount of thermal energy that is converted to electrical energy. This phenomena can be referred to as Kinetic Power Transient (KPT).

In the illustrated example of FIG. 1, the electrical element 104 is connected to a load 106. The load can be any device that consumes or stores electrical power (e.g., an electrical appliance). In operation, the pulse generator 102 can output an electrical pulse having a first electrical power. This causes the electrical element 104 to convert thermal energy into additional electrical energy. Accordingly, the pulse is applied to the load 106 with a second electrical power greater than the first electrical power.

If the pulse generator 102 continually outputs electrical pulses at periodic intervals, the electrical element 104 converts thermal energy to electrical energy with each pulse and increases the power of each pulse applied to the load 106. However, each time the electrical element 104 receives a pulse, it cools in order to convert thermal energy to electrical energy. As this happens, the temperature gradient between the electrical element 104 and the surrounding environment causes heat to be transferred from the environment to the electrical element, which causes the temperature of the electrical element to rise until it equalizes with the temperature of the environment. When the next electrical pulse is emitted by the pulse generator 102, the electrical element 104 again cools as it converts thermal energy to electrical energy. Thus, the amount of thermal energy that the electrical element 104 can convert into electrical energy is limited by the surrounding environment. In some examples, this cooling effect can allow the electrical element to be used as a cooling or refrigeration element.

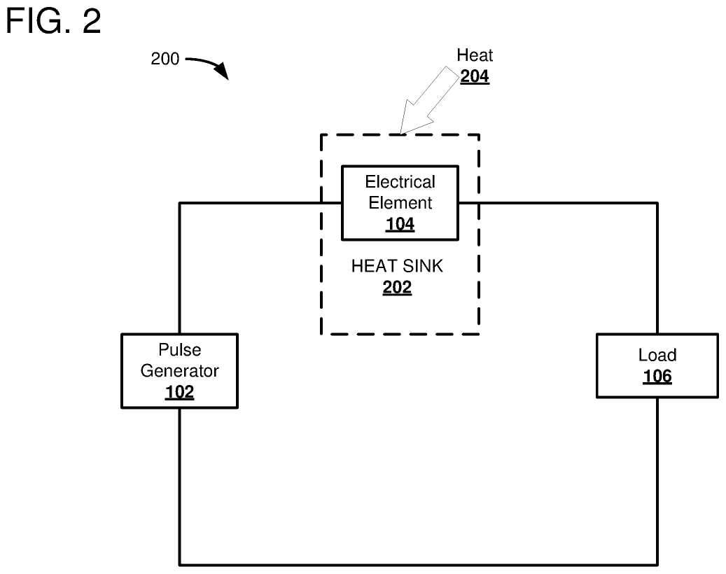

FIG. 2 shows an embodiment of a thermoelectric power generation system or circuit 200. In order to increase the capacity of the electrical element to convert thermal energy to electrical energy, an external heat source can be used. The circuit 200 is similar to the circuit 100 except that the circuit 200 includes a heat sink 202 coupled to the electrical element 104 and an external heat source 204 that applies heat to the electrical element and the heat sink. The heat sink 202 provides additional surface area that can allow for the absorption of additional heat from the heat source 204. The heat sink 202 can be thermally coupled to the electrical element 104 so as to allow heat transfer therebetween (e.g., direct contact). The heat source can include any source which is warmer than the electrical element including ambient air in which the heat sink resides.

In the example of FIG. 2, the pulse generator 102 continually applies electrical pulses having a high dV/dt ratio at periodic intervals. With each pulse, the electrical element 104 cools off and converts thermal energy to electrical energy. The load 106, thereby receives a pulse having a greater power than the power output by the pulse generator 102. By applying the external heat 204 to the heat sink 202, the electrical element 104 has constant source of additional thermal energy that can be converted to electrical energy. Thus, the electrical element 104 can continually increase the energy of the pulse produced by the pulse generator 102 that is applied to the load 106. The heat sink 202 can absorb the heat 204. In some examples, the heat 204 can be applied to the electrical element 104 such that there is a thermal gradient across a portion of the electrical element. The heat sink can be any of a variety of materials including a liquid (e.g., water, oil, etc.), a solid (e.g., metal), or a gas (e.g., air).

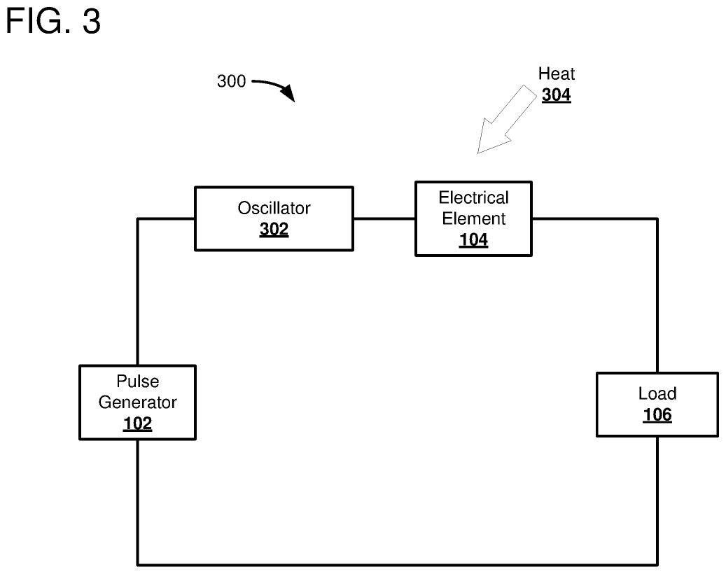

FIG. 3 shows an embodiment of a thermoelectric power generation system or circuit 300. The circuit 300 is similar to the circuit 200 of FIG. 2 except that the circuit 300 includes an oscillator 302 positioned between the pulse generator 102 and the electrical element 104. The oscillator 302 can be a harmonic oscillator and can output a periodic oscillating voltage when triggered by the pulse output by the pulse generator 102. Once triggered by a pulse output by the pulse generator 102, the oscillator 302 outputs a periodic signal to the electrical element 104. The strength of the signal output by the oscillator 302 decreases over time. However, each subsequent pulse output by the pulse generator 102 starts a new oscillation cycle. Thus, the oscillator 302 can be used to extend the amount of time that an input signal is supplied to the electrical element 104, even when the pulse generator 102 outputs a pulse having a very short pulse width.

In operation, the pulse generator 102 of FIG. 3 periodically outputs electrical pulses having a high dV/dt ratio. Each pulse can cause the oscillator 302 to output an oscillating signal to the electrical element 104. The electrical element 104 can cool off and convert thermal energy into electrical energy to increase the power of the electrical signal it receives. Heat 304 can be input to the electrical element 104 to provide additional thermal energy for the electrical element to convert to electrical energy. The signal with increased power can then be consumed by the load 106.

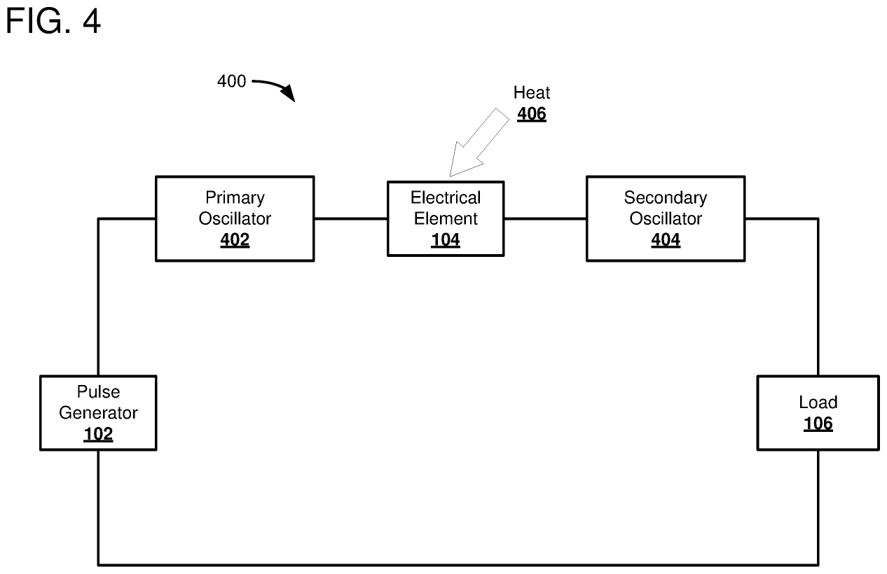

FIG. 4 shows an embodiment of a thermoelectric power generation system or circuit 400. The circuit 400 is similar to the circuit 300 of FIG. 3 except that the circuit 400 includes a primary oscillator 402 and a secondary oscillator 404. The primary oscillator 402 can be similar to the oscillator 302 of FIG. 3. The secondary oscillator 404 can be configured such that when the primary oscillator 402 outputs an oscillating signal in response to a pulse from the pulse generator 102, the secondary oscillator 404 outputs a resonant oscillating signal having a higher frequency than the oscillating signal output by the primary oscillator 402. As such, the secondary oscillator 404 can magnify the signal applied to the load 106. Like previous embodiments, a power output at the load 106 is greater than the energy input into the system by the pulse generator 102. The primary oscillator 402 and the second oscillator 404 are shown coupled in series on opposite side of the electrical element 104. Other configurations can also be used, such as both the primary and secondary oscillators being on a same side of the electrical element 104.

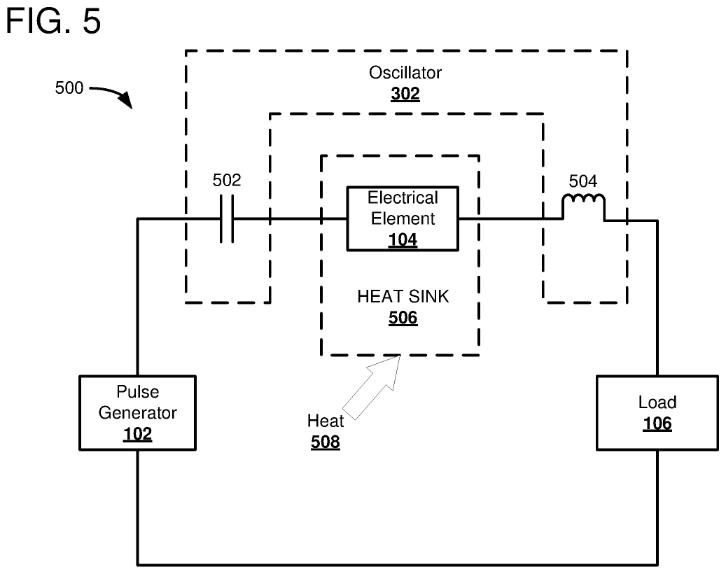

FIG. 5 shows an embodiment of a thermoelectric power generation system or circuit 500. The circuit 500 is similar to the circuit 300 except that the oscillator 302 specifically comprises a capacitor 502 and an inductor 504 to form an LC or tank circuit. Although the capacitor 502 and inductor 504 are shown coupled in series on opposite sides of the electrical element 104, they can be coupled in series and positioned together on one side of the electrical element. The circuit 500 further comprises a heat sink 506, similar to the heat sink 202 and a heat source 508, similar to the heat source 204. The circuit 500 can operate similar to the circuit 300 of FIG. 3, wherein the pulse generator 102 can generate either a single electrical pulse, or a series of electrical pulses having a high dV/dt ratio. The oscillator 302 can generate an oscillating signal in response to each pulse and the electrical element 104 can convert thermal energy into electrical energy by cooling off and increasing the power of the electrical pulses output by the pulse generator 102. The heat sink 506 can absorb the heat 508 to provide the electrical element 104 with a constant source of thermal energy that can be converted to electrical energy. Accordingly, the electrical power provided to the load 106 is greater than the electrical power produced by the pulse generator 102. The LC circuit of FIG. 5 can also be used as the secondary oscillator 404 of FIG. 4.

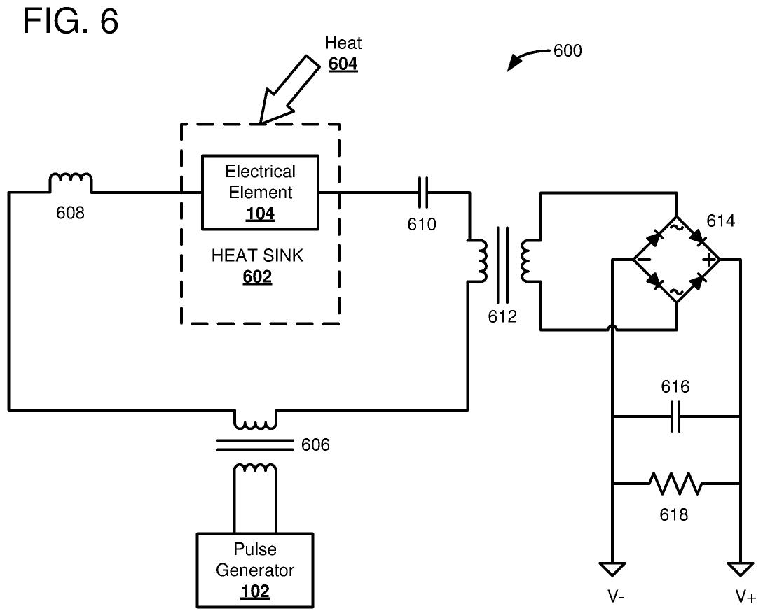

FIG. 6 shows an embodiment of a thermoelectric power generation system or circuit 600. The circuit 600 includes the pulse generator 102, the electrical element 104, a heat sink 602, and a heat source 604. The heat sink 602 and the heat source 604 can be similar to the heat sink 202 and the heat source 204, wherein the heat 604 is applied to the heat sink 602 to give the electrical element 104 a constant supply of thermal energy that can be converted to electrical energy. The pulse generator 102 can output electrical pulses having a high dV/dt ratio. The pulse generator 102 can be connected to a transformer 606, comprising two coils wrapped around a magnetic core or an air core. The transformer 606 can amplify the voltage output by the pulse generator 102.

The electrical element 104 can be positioned in series with an inductor 608 and a capacitor 610, which together can form an oscillator similar to the oscillator 302 of FIG. 5. The inductor 608 and the capacitor 610 can transform the pulses received by the pulse generator 102 into an oscillating signal. This oscillating signal can then be input to the electrical element 104. Because of the high dV/dt ratio of the pulses output by the pulse generator 102 and the KPT effect described above, the electrical element 104 can transform the thermal energy received from the heat source 604 into electrical energy, thereby increasing the power of the electrical signal output by the pulse generator.

An additional transformer 612 can receive the signal output by the electrical element 104 and can be connected to a full-bridge rectifier 614, which can convert the AC signal from the transformer 612 into a DC signal. In some examples, the full-bridge rectifier 614 can be replaced with a half-bridge rectifier. The outputs of the rectifier 614 can be connected to a load capacitor 616 and a load resistor 618. In some examples, the circuit 600 can include the capacitor 616 and not the load 618. In other examples, the circuit 600 can include the load 618 and not the capacitor 616. The capacitor 616 can store the electrical energy output by the rectifier 614. The load 618 can consume the electrical energy output by the rectifier 614.

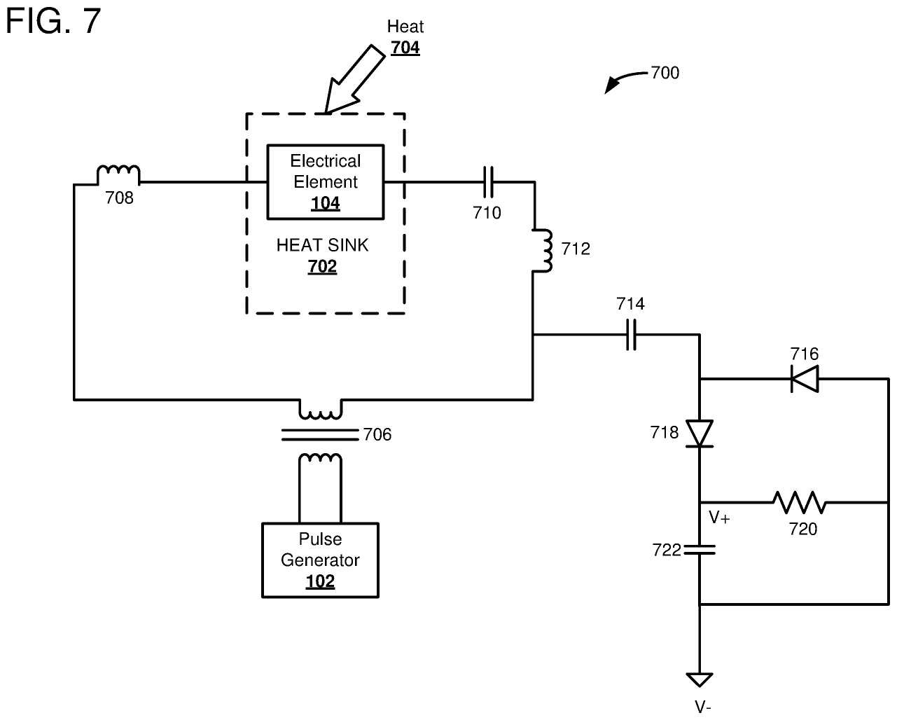

FIG. 7 shows an embodiment of a thermoelectric power generation system or circuit 700. The circuit 700 includes the pulse generator 102 and the electrical element 104. The circuit 700 can also include a heat sink 702 and a heat source 704, similar to the sink 602 and the heat source 604. The heat source 704 can apply heat to the heat sink 702 to supply the electrical element 104 with a constant supply of thermal energy that can be converted into electrical energy.

The pulse generator 102 can be connected to a transformer 706 that can amplify the electrical pulses output by the pulse generator. The circuit 700 can also include an inductor 708 and a capacitor 710 that can form a primary oscillator similar to the primary oscillator 402 of FIG. 4. The circuit 700 can also include an inductor 712, which along with the capacitor 710, can form a secondary oscillator similar to the secondary oscillator 404 of FIG. 4. The pulse generator 102 can output electrical pulses having a high dV/dt ratio. These pulses can cause the inductor 708 and the capacitor 710 to create a primary oscillating electrical signal, which can in turn cause the inductor 712 and the capacitor 710 to create a secondary oscillating signal having a higher frequency than the primary oscillating signal. The primary and secondary oscillating signals can cause the electrical element 104 to convert thermal energy from the heat source 704 into electrical energy, thereby increasing the power of the signal.

A capacitor tap 714 can withdraw energy output by the electrical element 104. The capacitor tap 714 can be connected to diodes 716 and 718, which can form a half-bridge rectifier, and which can convert AC power into DC power. The circuit output is shown as a resistor 720 and capacitor 722, which can consume and/or store electrical power. In some examples, the circuit 700 can include the resistor 720 without the capacitor 722. In other examples, the circuit 700 can include the capacitor 722 without the resistor 720.

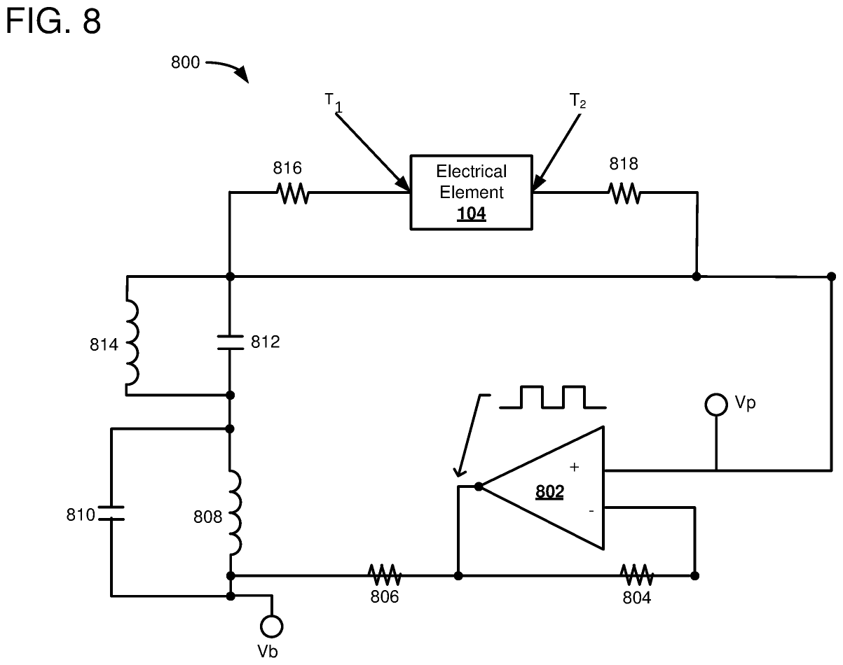

FIG. 8 shows an embodiment of a thermoelectric power generation system or circuit 800. The circuit 800 can include the electrical element 104 that can convert thermal energy into electrical energy as described above. In some examples, heat can be applied to the electrical element 104 such that the two ends of the electrical element are at two different temperatures T1 and T2. This creates a temperature gradient along the length of the electrical element 104 that can be converted into electrical energy.

The circuit 800 can include an op-amp 802, which can receive an input voltage Vp and output a square wave or other signal having a high dV/dt ratio, similar to the pulse generator 102 of FIGS. 1-7. The circuit 800 can further include resistors 804 and 806 that can be connected to the op-amp 802 as shown in FIG. 8. The circuit 800 can further include an inductor 808 in parallel with a capacitor 810 and a capacitor 812 in parallel with an inductor 814. The inductor 808 and the capacitor 810 can form a primary oscillator and the capacitor 812 and the inductor 814 can form a secondary oscillator. In some examples, one of the primary oscillator or the secondary oscillator can be omitted from the circuit 800. The output of the op-amp 802 can cause the primary oscillator to oscillate at a first frequency and the secondary oscillator to oscillate at a second frequency, greater than the first frequency.

These oscillations and the high dV/dt ratio of the signal output by the op-amp 802 can cause the electrical element 104 to convert thermal energy into electrical energy and increase the power of the received electrical signal. Resistors 816 and 818, which can represent a first and second load, can consume the electrical power output by the electrical element 104. In some examples, the resistors 816, 818 can have inductance, which may contribute to the oscillations.

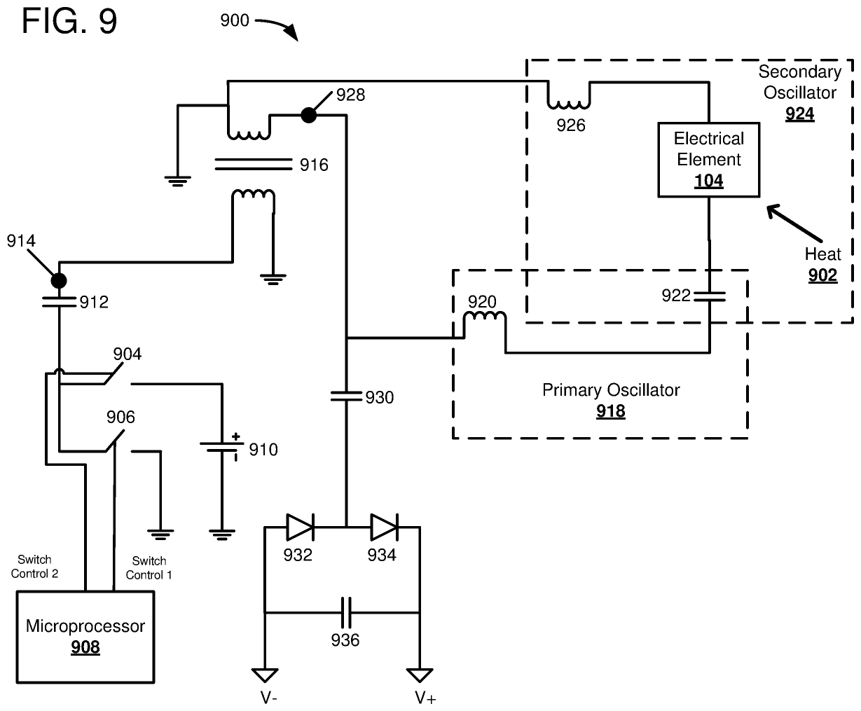

FIG. 9 shows an embodiment of a thermoelectric power generation system or circuit 900. The circuit 900 can include the electrical element 104 that can convert thermal energy into electrical energy as described above. The circuit 900 can further include a heat source 902 that can provide thermal energy to the electrical element 104 that can be converted into electrical energy. In some examples, the resistors 816, 818 can have inductance, which may contribute to the oscillations.

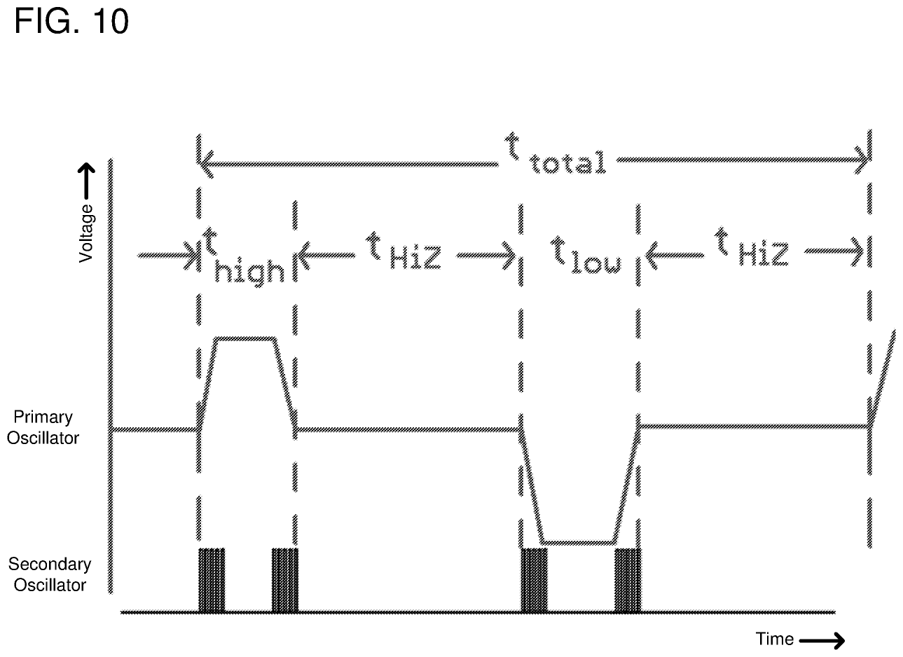

The circuit 900 can include a first switch 904 and a second switch 906 that can be controlled by a microprocessor 908. The microprocessor 908 can independently open and close the switches 904, 906. The first switch 904 can be connected to a power supply 910 and the second switch 906 can be connected to ground. The switches 904, 906 can be in parallel and can be connected to a capacitor 912. The microprocessor can alternatingly open and close the switches 904, 906 so as to output a square wave. During a first time interval, the microprocessor 908 can close switch 904 and open switch 906. This causes the voltage from the power supply 910 to be applied to the capacitor 912, thereby causing a positive voltage to accumulate on one plate of the capacitor. During a second time interval, the microprocessor 908 can open the switch 904 and close the switch 906. This grounds the capacitor, thereby causing a negative voltage to appear on the capacitor plate. This process can then be continued, with the microprocessor 908 repeatedly opening one of the switches 904, 906 and closing the other one, thereby producing an alternating series of positive and negative voltages to appear at point 914 of the circuit 900. FIG. 10 shows a time sequence of voltages at various points along the circuit 900. The primary oscillator voltage plot corresponds to the voltage at point 914 in the circuit 900. As described above, the voltage at this point is a square wave with a high dV/dt ratio. In some examples, the switches 904, 906 can be replaced with transistors (e.g., CMOS transistors).

The circuit 900 can further comprise a transformer 916 to amplify the voltage output created by the voltage source 910 and the switches 904, 906. The transformer 906 is connected to a primary oscillator 918 comprising an inductor 920 and a capacitor 922 and a secondary oscillator 924 comprising the capacitor 922 and an inductor 926. The primary oscillator 918 can be similar to the primary oscillator 402 of FIG. 4 and the secondary oscillator 924 can be similar to the secondary oscillator 404 of FIG. 4. The primary oscillator 918 can receive the voltage output by the voltage source 910 and the switches 904, 906 and generate a first oscillating signal and the secondary oscillator 924 can in turn create a secondary oscillating signal having a higher frequency than the first oscillating signal. The secondary oscillator voltage plot shown in FIG. 10 corresponds to this secondary oscillation present at point 928 in circuit 900. This secondary resonant or ringing oscillation amplifies and extends the voltage received by the electrical element 104. As the electrical element 104 receives this voltage, it converts thermal energy into electrical energy because of the KPT effect, thereby increasing the electrical power which is input to the electrical element. The circuit 900 further includes a capacitor 930 coupled to diodes 932, 934 that form a half-wave rectifier to convert the output AC signal to a DC signal. A capacitor 936 can store the electrical energy created by the circuit 900. In some examples, the capacitor 936 can be replaced with a load that consumes the electrical energy created by the circuit 900.

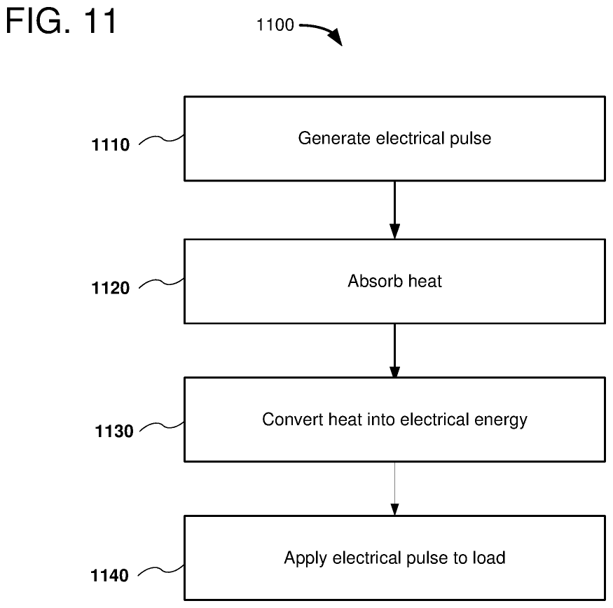

FIG. 11 is a flowchart 1100 outlining an example method of operating a thermoelectric power generation system or circuit as can be performed in certain examples of the disclosed technology. For example, the depicted method can be performed by the circuit 200.

At process block 1110, the pulse generator 102 generates an electrical pulse with a high dV/dt ratio. For example, in FIG. 9, the microprocessor 908 controls switches 904, 906 to generate an electrical pulse by closing switch 904 and opening switch 906 for a predetermined period of time and then opening switch 904 and closing switch 906. Such a pulse can be repeated at periodic intervals to further supply power to a load. At process block 1120, the electrical element 104 absorbs heat from its surrounding environment. For example, in FIG. 2, the electrical element 104 can receive heat 204 from a heat source or ambient air. Typically, the electrical element 104 has sufficient surface area to absorb heat. However, as shown in FIG. 2, the heat sink 202 can provide the surface area for heat absorption. At process block 1130, the electrical element 104 converts the absorbed heat into electrical energy. Pulsing of the pulse generator 102 applied to the electrical element 104 causes the electrical element to cool. The absorbed heat is thereby converted to electrical energy. At process block 1140, the electrical element 104 applies the electrical pulse to the load 106. Because of the KPT effect, the energy of the pulse applied to the load 106 is greater than the energy of the pulse output by the pulse generator 102.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope of these claims.

We claim:

1. An apparatus comprising:
a circuit including:
a pulse generator to generate an electrical pulse having a first power; and
a load; and
an electrical element coupled to the circuit;
wherein the electrical element is configured to receive heat that is converted into electrical energy by the circuit to apply a second power, greater than the first power, to the load.

2. The apparatus of claim 1, wherein at least a portion of the electrical element is coupled to a heat sink.

3. The apparatus of claim 2, wherein the heat is applied to the heat sink.

4. The apparatus of claim 1, wherein the heat is applied to the electrical element such that there is a thermal gradient across a length of at least a portion of the electrical element.

5. The apparatus of claim 1, wherein the electrical element comprises a wire having a greater surface area than conductors within the circuit that couple the electrical element to other circuit components by having one or more of the following:
a heavier gauge;
a longer length; or
a non-cylindrical shape with an increased surface area.

6. The apparatus of claim 1, wherein a portion of the electrical pulse generated by the pulse generator has a change in voltage with respect to time of at least 100 volts per microsecond.

7. The apparatus of claim 1, wherein the circuit further comprises an oscillator connected in series with the electrical element.

8. The apparatus of claim 1, wherein the circuit further comprises an oscillator connected in parallel with the electrical element.

9. The apparatus of claim 1, wherein the circuit further comprises a primary oscillator and a secondary oscillator connected in series with the electrical element.

10. The apparatus of claim 9, wherein at least one of the primary oscillator or the secondary oscillator is an LC circuit.

11. The apparatus of claim 9, wherein a rising voltage of the electrical pulse causes the primary oscillator to oscillate at a first frequency and the secondary oscillator to oscillate at a second frequency greater than the first frequency.

12. The apparatus of claim 9, wherein the circuit further comprises an inductive element and/or a capacitor tap connected in series with the secondary oscillator.

13. A method comprising:
generating an electrical pulse as an input to a circuit, wherein the circuit comprises a first portion including a load, and a second portion comprising an electrical element connected to the load;
absorbing heat within the electrical element;
converting the absorbed heat into electrical energy to increase a power of the electrical pulse; and
applying the electrical pulse with increased power to the load.

14. The method of claim 13, wherein at least a portion of the electrical element is coupled to a heat sink.

15. The method of claim 13, further comprising applying the heat to the electrical element such that there is a thermal gradient across a length of at least a portion of the electrical element.

16. The method of claim 13, wherein a portion of the electrical pulse has a change in voltage with respect to time of at least 100 volts per microsecond.

17. The method of claim 13, wherein the first portion of the circuit further comprises an oscillator positioned in series with the electrical element, wherein the oscillator causes the circuit to convert the absorbed heat into electrical energy.

18. The method of claim 13, wherein the first portion of the circuit further comprises a primary oscillator and a secondary oscillator connected in series with the electrical element.

19. The method of claim 19, wherein a rising voltage of the electrical pulse causes the primary oscillator to oscillate at a first frequency and the secondary oscillator to oscillate at a second frequency greater than the first frequency.

20. The method of claim 13, wherein generating the electrical pulse comprises:
during a first time interval, opening a second switch connected to ground and then closing a first switch connected to a power supply; and
during a second time interval, opening the first switch and then closing the second switch.
